(19) United States
(12) Patent Application Publication
(10) Pub. No.: US 2021/0159722 A1
(43) Pub. Date: May 27, 2021

(54) LED Based Light Sensor Circuitry for Gating Solar Panel Power

(71) Applicant: Mageshkumar Kuppusamy, Folsom, CA (US)

(72) Inventor: Mageshkumar Kuppusamy, Folsom, CA (US)

(21) Appl. No.: 17/104,226

(22) Filed: Nov. 25, 2020

Related U.S. Application Data
(60) Provisional application No. 62/939,683, filed on Nov. 25, 2019.

(51) Int. Cl. H02J 7/35; H01L 31/0232; H02S 50/00; H02J 7/00

(52) U.S. Cl. CPC H02J 7/35; H01L 31/02325; H01L 31/125; H02J 7/0047; H02J 7/007; H02S 50/00

(57) ABSTRACT

An LED based light sensor circuitry for gating a solar panel power is shown and described. The light measuring circuit is comprised of a circuit board containing a plurality of LED lights, a low pass filter, and an amplifier. Further, the LED lights will produce a power output when sunlight enters a lens of each LED light. The light measuring circuit is electrically coupled to power gating circuitry within the circuit system. The power gating circuitry will activate the power switch only when the light measuring circuit or light sensor circuit produces an adequate amount of power indicating that enough light is being received and the light is plus or minus thirty degrees from the center axis of the LED lights.

### CROSS REFERENCE TO RELATED APPLICATIONS

This application claims the benefit of U.S. Provisional Application No. 62/939,683 filed on Nov. 25, 2019. The above identified patent application is herein incorporated by reference in its entirety to provide continuity of disclosure.

### BACKGROUND OF THE INVENTION

The present invention relates to an LED based light sensor circuitry for gating a power source. More particularly, the present invention provides light sensing circuitry to operate a power gate on a solar panel.

With the rise of technology has come the rise of smart devices. All of these devices need a constant power source to properly operate. In some instances, a direct connection to a power source is possible. In other scenarios, a battery may be used. Batteries have the drawback of needing to be charged once the limited power supply is depleted. A solar panel is a modern solution to both provide power and charge existing batteries used as a power source.

However, the current system in which solar panels are deployed has the potential to deplete energy faster than it is gained. Solar panels only work at peak capacity for a limited number of hours. During other hours the solar panel is in direct sun light. In these off-peak hours, the solar panel may not generate enough power to satisfy the connected device. This can cause a severe problem in battery operated devices like security cameras.

Many of these devices are not equipped with a power gate. Devices like secure cameras are turned on when power of any amount is sensed from the solar panel. In some instances, during off peak hours the devices will be turned on but it will not have adequate solar power supply. The device will trigger a power negotiation protocol when it does not have adequate power but the solar panel could not provide the needed power dude to off-peak sunlight. Due to constant power negotiation by the device, it will deplete its battery eventually leading to the device shutting down.

The power gate triggers when power of any amount is sensed from the solar panel. In some instances, the gate will be triggered, and the device will not have an adequate power supply. This means that the device will be in a constant state of flux where the solar panel is triggered then the device has to request more power shutting the gate. This can in fact deplete the battery faster than if the device is solely running off of battery power.

In the present invention, this LED based light sensor circuitry is special comparted to other light sensors like a photodiode or a phototransistor in that it can be used to measure both the intensity of light and the angle of light. Photodiodes and phototransistors can only measure the intensity of light but cannot provide any indication of the angle of sunlight. This angle of sunlight measurement is used to identify the times at which the solar panel can provide stable power and guarantee a minimum needed power level for connected devices.

Consequently, there is a need for an improvement in the art of light sensor circuitry for gating a solar panel that can detect both the amount of sunlight and the peak sunlight hours by detecting if the sun is directly above the solar panel. The present invention substantially diverges in design elements from the known art while at the same time solves a problem many people face when using a solar panel to power electronic devices. In this regard the present invention substantially fulfills these needs.

### SUMMARY OF THE INVENTION

The present invention provides an LED based light sensor circuitry for gating a solar panel wherein the same can be utilized for providing convenience for the user when using a solar panel to power an electronic device. The LED light circuitry for gating a solar panel is comprised of a solar panel electrically coupled within a circuit system. A light measuring circuit is electrically coupled within the circuit system, wherein the light measuring circuit is comprised of a circuit board containing a plurality of LED lights. Further, the LED lights will produce a power output when sunlight enters a lens of each LED light. The light measuring circuit is electrically coupled to power gating circuitry within the circuit system. The power gating circuitry will activate the gate only when light measuring circuit produces an adequate amount of power indicating that enough light is being received.

Another object of the LED light circuitry for gating a solar panel is to provide a light measuring circuit that is connected the exterior edge of the solar panel.

Another object of the LED light circuitry for gating a solar panel is to provide a gating circuitry that will allow power from the solar panel when the light measuring circuit registers enough light.

Another object of the LED light circuitry for gating a solar panel is to provide LED lights that are green.

Another object of the LED light circuitry for gating a solar panel is to provide LED lights that are red.

Another object of the LED light circuitry for gating a solar panel is to provide a lens of the LED light that amplifies light.

Another object of the LED light circuitry for gating a solar panel is to provide a lens of the LED light that amplifies light when the light enters at an angle measuring between zero and twenty degrees of a center line rising directly from the center of the lens.

Another object of the LED light circuitry for gating a solar panel is to provide an electric device electrically coupled within the circuit system.

Another object of the LED light circuitry for gating a solar panel is to provide a voltage regulator electrically coupled within the circuit system.

Another object of the LED light circuitry for gating a solar panel is to provide an electric device controller coupled within the circuit system.

Another object of the LED light circuitry for gating a solar panel is to provide an electric device rechargeable power source electrically coupled within the circuit system.

Other objects, features, and advantages of the present invention will become apparent from the following detailed description taken in conjunction with the accompanying drawings.

### BRIEF DESCRIPTION OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a wiring diagram of an embodiment of the LED based light sensor circuitry for gating a solar panel.

FIG. 2 shows a perspective view of an embodiment of a light measuring circuitry attached to a solar panel.

FIG. 3 shows a wiring diagram of an alternative embodiment of the LED based light sensor circuitry for gating a solar panel.

FIG. 4 shows a wiring diagram of an alternative embodiment of the LED based light sensor circuitry for gating a solar panel.

FIG. 5 shows a wiring diagram of an alternative embodiment of the LED based light sensor circuitry for gating a solar panel.

FIG. 6 shows a wiring diagram of an alternative embodiment of the LED based light sensor circuitry for gating a solar panel.

FIG. 7 shows a wiring diagram of an alternative embodiment of the LED based light sensor circuitry for gating a solar panel.

### LIST OF REFERENCE NUMERALS

With regard to the reference numerals used, the following numbering is used throughout the drawings.
101 LED Array
102 Voltage Regulator
103 Supervisory Circuit
104 Gating Circuitry
105 Solar Panel
106 Voltage Regulator
107 Device Controller
108 Device
201 Wire Connection
202 Wire Connection
203 Array Bracket
204 LED Lights
205 Light Element
206a Lower Section of Light Housing
206b Upper Section of Light Housing
207 Lens
401 Secondary Power Source
501 Electronic System

### DETAILED DESCRIPTION OF THE INVENTION

Reference is made herein to the attached drawings. Like reference numerals are used throughout the drawings to depict like or similar elements of the LED light circuitry for gating a solar panel. For the purposes of presenting a brief and clear description of the present invention, a preferred embodiment will be discussed as used for the LED light circuitry for gating a solar panel. The figures are intended for representative purposes only and should not be considered to be limiting in any respect.

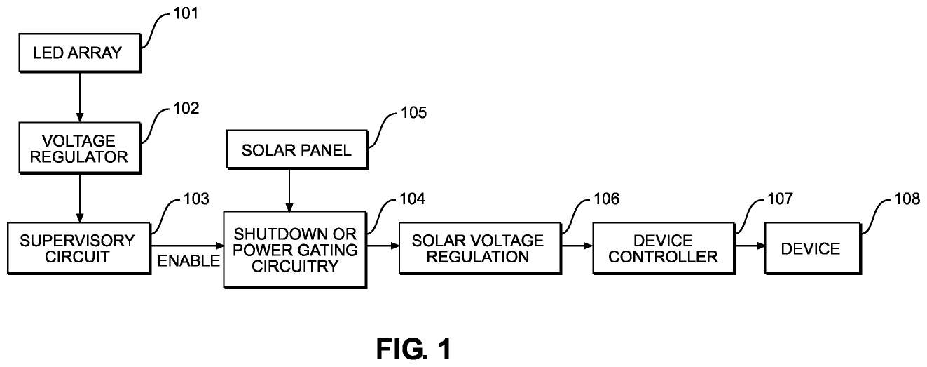

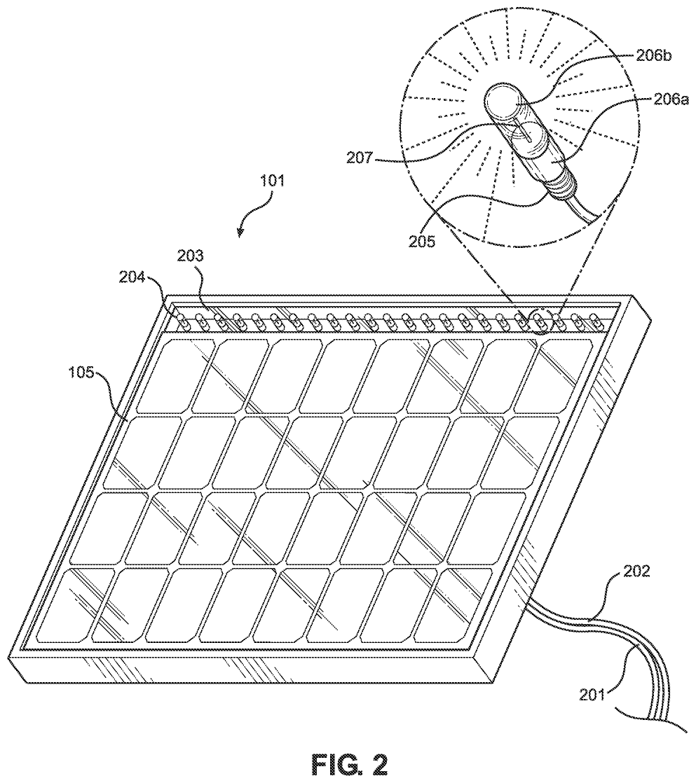

Referring now to FIG. 1, there is shown a wiring diagram of an embodiment of the LED light circuitry for gating a solar panel. The LED light circuitry includes an LED array 101. The LED array 101 includes a plurality of LED lights. A further description of the physical descriptions of the LED lights will be given in FIG. 2. The LED lights are wired together to create the LED array 101. In one embodiment the LED lights in the LED array 101 are green lights. Green LED lights have been shown to produce the most electric current. In another embodiment the LED lights in the LED light array 101 are red lights. Red LED lights have been shown to produce the second most electric current. In yet further embodiments other LED light colors are used in the LED light array 101. While a multitude of colors may be used to create the LED array 101, different numbers of LED lights will be required to operate the circuitry.

In the shown embodiment the LED array 101 is electrically coupled to a voltage regulator 102. The voltage regulator 102 will ensure that only a limited amount of voltage is allowed from the LED array 101. The voltage regulator 102 is electrically coupled to a supervisory circuit 103. In one embodiment the supervisory circuit 103 is a microcontroller. The supervisory circuit 103 is coupled to a gating circuitry 104.

A solar panel 105 is further electrically coupled to the gating circuitry 104. When the supervisory circuit 103 determines that enough voltage has been generated by the LED array 101 it will open the gating circuitry 104. See a further description of this generation in the description of FIG. 2. When the gating circuitry 104 is opened, energy from the solar panel 105 will pass through the gating circuitry 104.

The gating circuitry 104 sends electricity through a second voltage regulator 106. This will ensure that the energy generated by the solar panel 105 does not surpass a threshold limit. In different embodiments the second voltage regulator 106 is set to different thresholds as required by a connected device 108.

The second voltage regulator 106 is connected to a device controller 107. The device controller 107 will, at least in relevant part, determine if the connected device 108 should draw power from solar power or from an internal power source. The device controller 107 will be connected to a device 108. In one embodiment the device 108 is a camera. In another embodiment the device 108 is a doorbell. In yet a further embodiment the device 108 is any other item that is at least partially powered by a solar panel.

Referring now to FIG. 2, there is shown a perspective view of an embodiment of a light measuring circuitry attached to a solar panel. This FIG. shows the solar panel 105 having wire connections 202 and 201 leaving the solar panel. The wire connections 202 and 201 will lead to the rest of the electronic connections as described herein. In the shown embodiment the LED array 101 is shown attached to an edge of the solar panel 105. In other embodiments the LED array 101 is attached to a different side of the solar panel 105. In yet a further embodiment the LED array 101 is not attached to the solar panel 105 but is positioned near said solar panel 105.

The LED array 101 is comprised of an array bracket 203. The array bracket 203 houses a plurality of LED lights 204. The LED lights 204 will generate a small amount of electricity when sunlight is shown through the LED lights 204. The more direct the sunlight, the more electricity the LED lights 204 will produce. As discussed above the different colors of LED lights 204 will require more or less sunlight to produce the desired effects.

In the shown embodiment each LED light is comprised of a light element 205. The light element is contained in a light housing 206a, 206b. A lower section of the light housing 206a will house the light element 205. There is a lens 207 located between the lower section of the light housing 206a and an upper section of the light housing 206b. The lens 207 and the light housing 206a, 206b create a focusing element. Light will be greater when more directly focused through the lens. The light housing includes an upper section 206b. The upper section 206b creates a top cap of the housing. This will protect the lens 207 and the light element 205.

LED lights 204 are built such that when light shines upon them they will generate a limited amount of electric current. The LED array 101 is configured such that only sunlight entering the LED lights 204 are a specific angle will activate a gating circuit. This angle will correspond with the angle of sun light that is sufficient to provide ample sun light to the solar panel 105. This will ensure that the solar panel 105 is only allowed to send power to an electric device when the solar panel 105 will have enough energy to power the electric device.

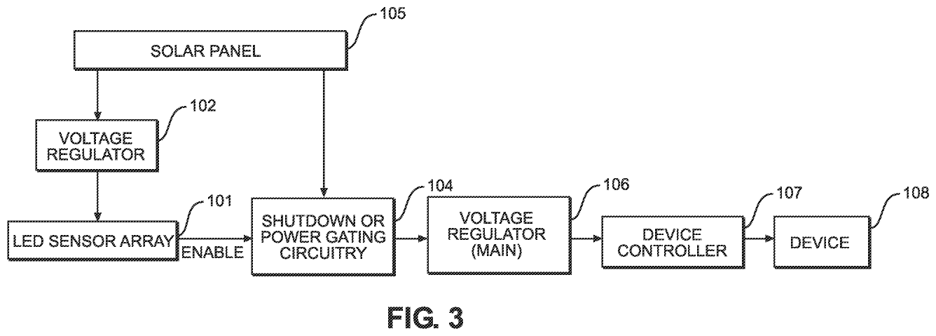

Referring now to FIG. 3, there is shown a wiring diagram of an alternative embodiment of the LED light circuitry for gating a solar panel. In the alternative embodiment, the solar panel 105 is electrically coupled to the voltage regulator 102 and the gating circuitry 104. The voltage regulator 102 is then electrically coupled to the LED array 101. The LED array 101 is electrically coupled to the gating circuitry 104. The gating circuitry 104 is then electrically coupled to a second voltage regulator 106. The second voltage regulator is electrically coupled to a device controller 107. The device controller is coupled to a desired device 108.

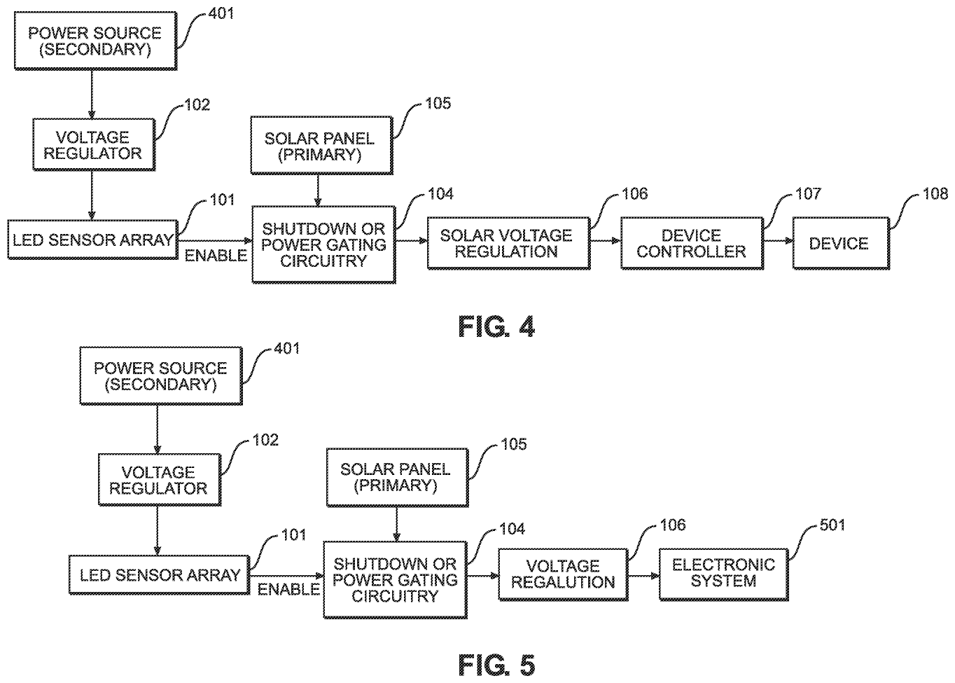

Referring now to FIG. 4, there is shown a wiring diagram of an alternative embodiment of the LED light circuitry for gating a solar panel. This alternative embodiment has a secondary power source 401 coupled to the voltage regulator 102. In one embodiment the secondary power source 401 is a wired electrical connection. In another embodiment the secondary power source 401 is a battery. In yet a further embodiment the secondary power source 401 is a second solar panel. The secondary power source 401 is connected to the voltage regulator 102. The voltage regulator 102 is electrically coupled to the LED array 101. The LED array 101 is coupled to the gating circuitry 104. The solar panel 105 is directly coupled to the gating circuitry 104.

The gating circuitry 104 is then electrically coupled to a second voltage regulator 106. The second voltage regulator is electrically coupled to a device controller 107. The device controller is coupled to a desired device 108.

Referring now to FIG. 5, there is shown a wiring diagram of an alternative embodiment of the LED light circuitry for gating a solar panel. The alternative embodiment shown in FIG. 5 is the same as shown in FIG. 4 except for the electronic system 501 connected after the second voltage regulator 106. The second voltage regulator 106 is connected to an electronic system 501. The electronic system 501 may be all manner of items that can be operated by solar power. In one embodiment the electronic system 501 is a plurality of cameras wired into a system.

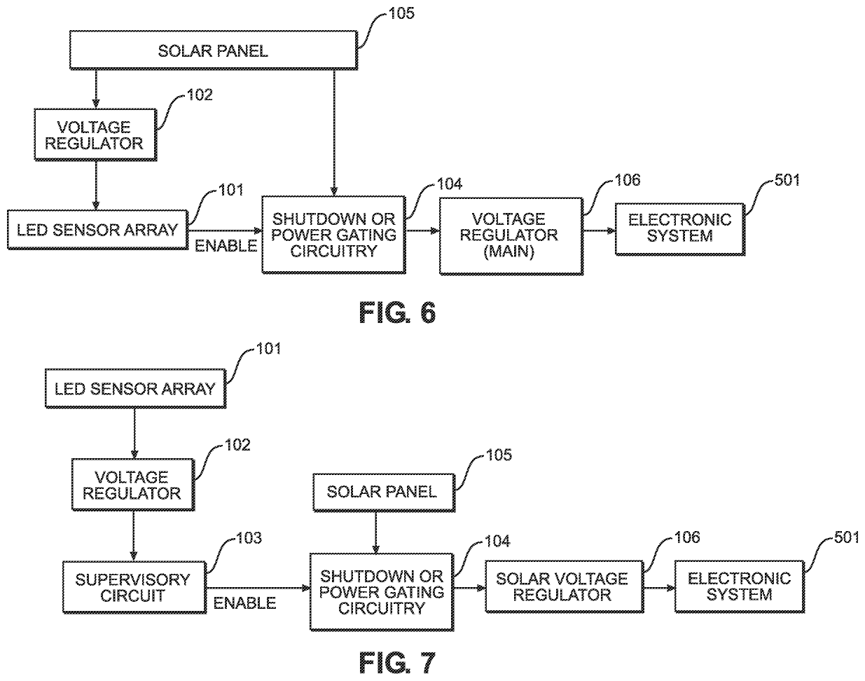

Referring now to FIG. 6, there is shown a wiring diagram of an alternative embodiment of the LED light circuitry for gating a solar panel. The alternative embodiment shown in FIG. 6 is the same as shown in FIG. 3 except for the electronic system 501 connected after the second voltage regulator 106. The second voltage regulator 106 is connected to an electronic system 501. The electronic system 501 may be all manner of items that can be operated by solar power. In one embodiment the electronic system 501 is a plurality of cameras wired into a system.

Referring now to FIG. 7, there is shown a wiring diagram of an alternative embodiment of the LED light circuitry for gating a solar panel. The alternative embodiment shown in FIG. 7 is the same as shown in FIG. 1 except for the electronic system 501 connected after the second voltage regulator 106. The second voltage regulator 106 is connected to an electronic system 501. The electronic system 501 may be all manner of items that can be operated by solar power. In one embodiment the electronic system 501 is a plurality of cameras wired into a system.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) A LED based light sensor circuitry for gating a solar panel, the circuitry comprising:
a light measuring sensor circuit, wherein the light measuring circuit is comprised of a circuit board containing a plurality of LED lights;
wherein the LED lights will produce a power output when sunlight enters a lens of each LED light;
the light measuring circuit is electrically coupled to power gating circuitry, wherein the power gating circuitry will activate the gate only when the light measuring circuit produces an adequate amount of power indicating that enough light is being received and the light is detected at an angle of thirty degrees relative to the sensor.

2) The LED based light sensor circuitry for gating a solar panel of claim 1, wherein the gating circuitry will allow power from a connected power supply to an electronic device when the light measuring circuit registers enough light.

3) The LED based light sensor circuitry for gating a solar panel of claim 1, wherein the LED lights are green.

4) The LED based light sensor circuitry for gating a solar panel of claim 1, wherein the LED lights are red.

5) The LED based light sensor circuitry for gating a solar panel of claim 1, wherein the lens of the LED light amplifies light.

6) The LED light circuitry for gating a solar panel of claim 5, wherein the lens amplifies light when the light enters at an angle measuring between zero and thirty degrees of a center line rising directly from the center of the lens.

7) A LED based light sensor circuitry for gating a solar panel, the circuitry comprising:
a solar panel electrical coupled within a circuit system;
a light measuring circuit electrically coupled within the circuit system, wherein the light measuring circuit is comprised of a circuit board containing a plurality of LED lights; and
wherein the LED lights will produce a power output when sunlight enters a lens of each LED light;
the light measuring circuit is electrically coupled to power gating circuitry within the circuit system, wherein the power gating circuitry will activate the gate only when light measuring circuit produces an adequate amount of power indicating that enough light is being received.

8) The LED based light sensor circuitry for gating a solar panel of claim 7, wherein the light measuring circuit is located around the solar panel.

9) The LED based light sensor circuitry for gating a solar panel of claim 7, wherein the gating circuitry will allow power from the solar panel to an electronic device when the light measuring circuit registers enough light.

10) The LED based light sensor circuitry for gating a solar panel of claim 7, wherein the LED lights are green.

11) The LED based light sensor circuitry for gating a solar panel of claim 7, wherein the LED lights are red.

12) The LED based light sensor circuitry for gating a solar panel of claim 7, wherein the lens of the LED light amplifies light.

13) The LED based light sensor circuitry for gating a solar panel of claim 12, wherein the lens amplifies light when the light enters at an angle measuring between zero and twenty degrees of a center line rising directly from the center of the lens.

14) The LED based light sensor circuitry for gating a solar panel of claim 7, further comprising a second solar panel electrically coupled within the circuit system.

15) The LED based light sensor circuitry for gating a solar panel of claim 7, further comprising an electric device electrically coupled within the circuit system.

16) The LED based light sensor circuitry for gating a solar panel of claim 7, further comprising a voltage regulator electrically coupled within the circuit system.

17) The LED based light sensor circuitry for gating a solar panel of claim 7, further comprising an electric device controller coupled within the circuit system.

18) The LED based light sensor circuitry for gating a solar panel of claim 7, further comprising an electric device rechargeable power source electrically coupled within the circuit system.
